(19) United States
(12) Patent Application Publication
(10) Pub. No.: US 2012/0129344 A1
(43) Pub. Date: May 24, 2012

(54) PROCESS AND APPARATUS FOR REMOVAL OF CONTAMINATING MATERIAL FROM SUBSTRATES

(76) Inventors: Helmuth Treichel, Milpitas, CA (US); Dave Bohling, Fort Collins, CO (US); Jeffrey Farber, Delmar, NY (US)

(21) Appl. No.: 13/263,639

(22) PCT Filed: Apr. 8, 2010
(86) PCT No.: PCT/US2010/030349

§ 371 Date: Feb. 6, 2012

Related U.S. Application Data
(60) Provisional application No. 61/167,641, filed on Apr. 8, 2009.
(60) Provisional application No. 61/248,620, filed on Oct. 5, 2009.

(51) Int. Cl. H01L 21/306; C11D 7/60

(52) U.S. Cl. 438/690; 510/175; 257/E21.215

(57) ABSTRACT

A process for removing contaminating metals from a substrate to improve electrical performance is provided. Polycationic metals are known to be particularly detrimental to the electrical properties of an insulator or semiconductor substrate. The process includes the exposure of the substrate to an aqueous solution of at least one compound of the formula: (I) where n in each occurrence is independently an integer value between 0 and 6, and X is independently in each occurrence H, NR₄, Li, Na or K and at least one of X is NR₄; where R in each occurrence is independently H or C₁-C₆ alkyl, to improve electrical performance of the substrate. A kit for preparing such a solution includes a 1-20 total weight percent aqueous concentrate of at least one compound of formula (I). The kit also provides instructions for the dilution of the concentrate to form the solution.

### CROSS-REFERENCE TO RELATED APPLICATIONS

This application claims priority of U.S. Provisional Patent Applications 61/167,641 filed Apr. 8, 2009, and 61/248,620 filed Oct. 5, 2009, which are incorporated herein by reference.

### FIELD OF THE INVENTION

The present invention relates to the field of removal of contaminating materials from substrates and in particular the aqueous treatment and chelation of liberated metal contaminants from a silicon substrate.

### BACKGROUND OF THE INVENTION

In processing photovoltaic (solar) substrates, layers are often deposited on the photovoltaic (solar) substrate. For instance, during fabrication of some photovoltaic (solar) substrates, one or more layers are often applied to one side of a photovoltaic (solar) substrate (e.g., by electroplating or physical vapor deposition or chemical vapor deposition). The presence of metallics (e.g., iron, copper) and particles on the substrate cause problems in subsequent fabrication, e.g. as to adhesion strength and/or uniformity. For instance, during subsequent fabrication on the substrate deposited films can flake off due to bad adhesion caused by surface contamination (particles and trace metals), thereby causing more particulate problems and cross-contamination. Additionally, such contaminants reduce solar conversion efficiency. Light elements like oxygen, carbon and nitrogen generate heterogeneous nucleation centers for metallic precipitation (e.g., Fe, Cr and Ni) which are acting as deep traps and are responsible for degrading the overall cell conversion efficiency by reducing the minority carrier diffusion length [Dissertation: INDRADEEP SEN, NCSU, 2002].

The reasons for diminished efficiencies include incomplete absorption of light or dissipation of a part of the photon energy as heat, imperfect junctions, recombination effects within the bulk and surfaces, and series and shunt resistance effects. Instead of avoiding impurities by “creative” or “intelligent” cleaning, the solar industry uses various gettering and removal steps to minimize these issues. Impurities are the major contributors of electrical activity of defects and their removal or minimization is therefore of utmost importance. The metallic impurities have a stronger impact on the lifetime due to their deeper energy levels in the silicon band gap. Extended defects are generated due to interaction of point defects with metallic and non-metallic impurities. Heavy metals, such as iron (Fe), nickel (Ni) and copper (Cu) diffuse very fast into and through a silicon matrix (e.g., the diffusion velocity of an iron atom at 1100° C. is of the order of 1 μm/sec). Once within the crystal, impurities in isolation can act as strong recombination centers or can be precipitated at crystallographic defects, with the combined defect acting as an effective recombination site. The recombination properties of extended crystal defects are mainly defined by the metallic impurities decorating the particular defects. Therefore, if defects are present near the junction or in the region within one or two diffusion lengths of the junction, it can result in a sharp decrease in V_{OC} (open circuit voltage) of the device if these defects are decorated with metals. Without removal of these metallic impurities from the active device regions or render them electrically inactive PV performance is diminished and even prevented. The global defect model for PV silicon suggests a strong relationship between metallic impurities and crystal defects which are responsible for lowering the overall cell efficiency. The effective lifetime is largely limited by the iron concentration. [“Direct correlation of transition metal impurities and minority carrier recombination in multicrystalline silicon”, Scott A. McHugo and A. C. Thompson, Lawrence Berkeley National Laboratory, Berkeley, Calif. 94720, Perichaud and S. Martinuzzi, Appl. Phys. Lett. 72, 3482 (1998); DOI:10.1063/1.121673]

Solutions to this problem have been proposed and it has been shown that there is a direct correlation of transition metal impurities and minority carrier recombination. Others have shown a tendency toward improved performance with more intensive cleaning. Effective free electron lifetimes are known to increase with more thorough cleaning. Additionally, metals present in high enough concentrations (i.e., clusters of precipitates) in the pn junction area adjacent to the current collecting channel might trap charges near the interface, pin the Fermi level near midgap, and contribute to lowering the potential barrier height. The diffusion of various metals into silicon to diminish PV operation has thermodynamically insignificant barriers for metals. In addition to iron these also include copper, manganese, chromium and nickel.

Thus, there exists a need for a cleaning process and compositions that afford superior removal of impurities from substrates and in particular photovoltaic substrates [S. Keipert et al., 23rd European Photovoltaic Solar Energy Conference and Exhibition, 1-5 Sep. 2008, Valencia, Spain].

### SUMMARY OF THE PRESENT INVENTION

A process for removing contaminating metals from a substrate to improve electrical performance is provided. Polycationic metals are known to be particularly detrimental to the electrical properties of an insulator or semiconductor substrate. The process includes the exposure of the insulator or semiconductor substrate to an aqueous solution of at least one compound of the formula:

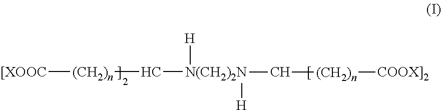

where n in each occurrence is independently an integer value between 0 and 6, and X is independently in each occurrence H, NR₄, Li, Na or K and at least one of X is NR₄; where R in each occurrence is independently H or C₁-C₆ alkyl, to improve electrical performance of the substrate. The process is noted to be particularly advantageous when the compound of Formula (I) is present in the solution with peroxides as peroxide stability is enhanced. A kit for preparing a solution for removing metal contaminants from an insulator or semiconductor substrate to improve electrical performance includes a 1-20 total weight percent aqueous concentrate of at least one compound of the formula:

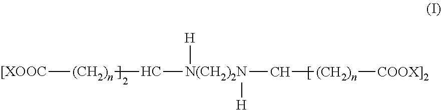

where n in each occurrence is independently an integer value between 0 and 6, and X is H, NR₄, Li or K; where R in each occurrence is independently H or C₁-C₆ alkyl. The kit also provides instructions for the dilution of the concentrate to form the solution for removing contaminating metals from the insulator or semiconductor substrate so as to improve electrical performance thereof.

### BRIEF DESCRIPTION OF THE DRAWINGS

The present invention will be understood more fully from the detailed description given below and from the accompanying drawings of various embodiments of the invention, which, however, should not be taken to limit the invention to the specific embodiments, but are for explanation and understanding only.

FIG. 1A is a schematic flowchart of a cleaning process according to the present invention;

FIG. 1B is a preferred schematic flowchart for a photovoltaic with dashed line boxes (steps that can be omitted) and bold line boxes (steps that can contain ethylene diamine tetracid (I)) relative to the conventional process;

FIG. 2 is a schematic flowchart of an alternate cleaning process according to the present invention;

FIG. 3 is a bar graph of measured open circuit voltage for reduced substrates treated by conventional and inventive processes; and

FIG. 4 is a bar graph of carrier lifetime based on iron contamination levels for an inventive cleaning relative to intentional contamination and standard HF cleaning.

### DETAILED DESCRIPTION OF THE INVENTION

The present invention has utility as cleaning solutions and processes for removing contaminating materials from a substrate. Improved photovoltaic device operational parameters are provided through application of an inventive process to the photovoltaic substrate. While the present invention is detailed with respect to silicon substrates of either separate silicon wafer or continuous ribbon substrates, it is appreciated that the inventive cleaning compositions and process are also applicable to silicon substrates used for other applications as well as substrates other than single crystal silicon. Other applications of silicon substrates that benefit from the present invention include LEDs, compound semiconductors, MEMS devices, and sensors. It is appreciated that silicon substrates include polycrystalline, amorphous and crystalline silicon substrates. Other substrates operative herein illustratively include silicon on insulator (SOI), glass, sapphire, silicon carbide, silicon nitride, polymers or organic sheets, and compound semiconductors.

While the present invention is largely detailed hereafter with respect to photovoltaic substrates, it should be noted that the other aforementioned applications benefit from removal of metal contaminants. It is appreciated that surfaces can be exposed through etch. Substrates typically have organic surface contaminants such as oils, while metal ions are typically but not exclusively found within the body of the substrate with particular metal ions within preferentially segregating into portions of the substrate. Without intending to be bound by a particular theory, the present invention chelates metal atoms and/or metal ions that are exposed on a substrate surface through solvated chelating agent interaction. The metal ions can be interstitial, substitutional, or even form clusters within the substrate or on compositional interface. An additional requirement of photovoltaic substrate cleaning methodology relative to that for an integrated circuit substrate is the desire to induce a bulk etch and surface roughening to promote internal scattering of incident light within the resultant photovoltaic thereby enhancing the likelihood of photovoltaic excitation to create free electrons.

As used herein with respect to chelating agents, specifically including ethylenediamine tetraacids and citric acid containing compounds, it is appreciated that the salts of such acids are also operative herein and intended to be encompassed by reference to such chelating agents.

An inventive process eliminates or operates synergistically with prior art process steps and more efficiently removes substrate contaminants and particular metal ions therefrom.

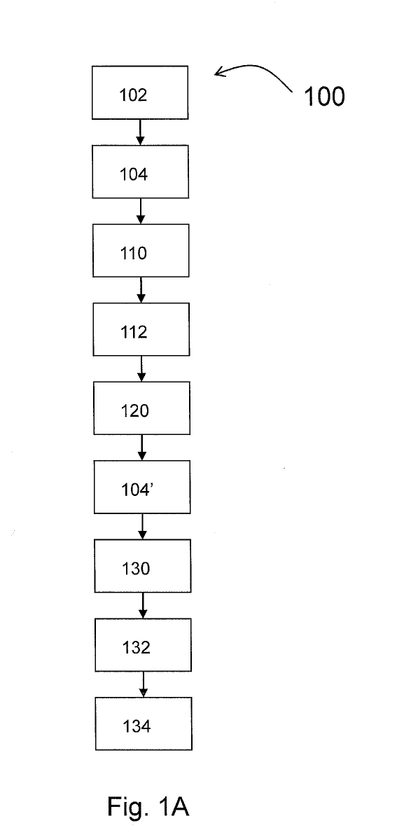

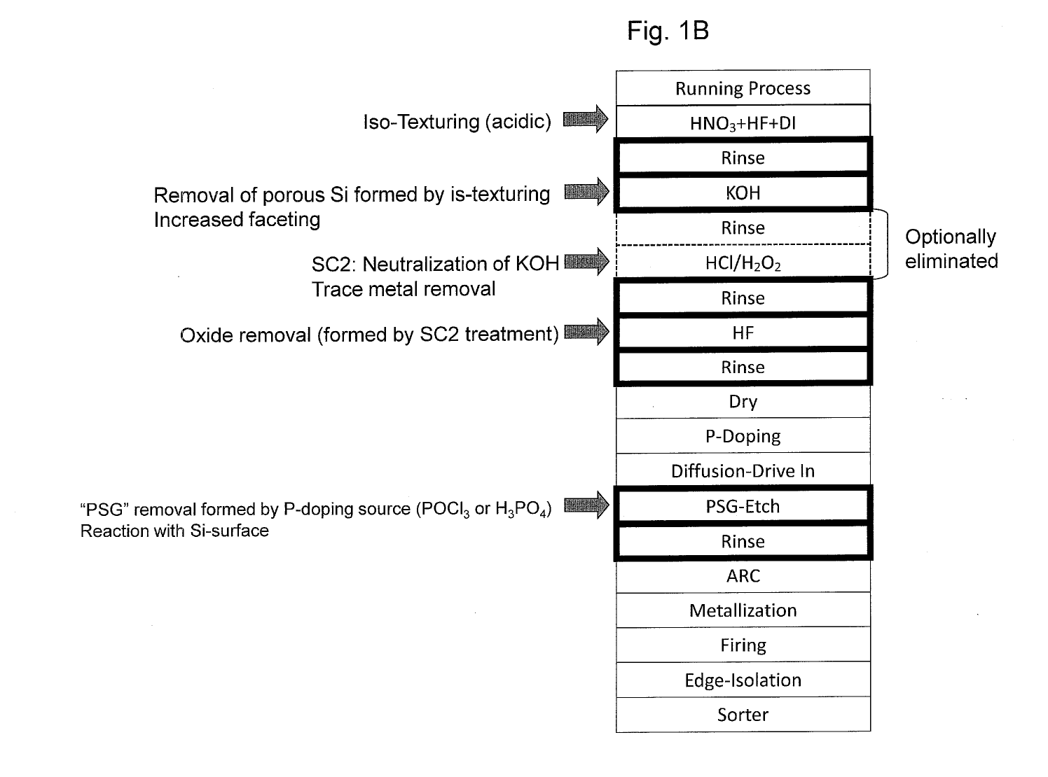

Referring now to FIG. 1A, an inventive process is shown generally at 100 as a flowchart illustrating cleaning of a substrate having a hydrophobic surface such as silicon. Process 100 is characterized by three essential steps of removing a native oxide from a photovoltaic substrate 110, performing a bulk etch and surface roughening 120 and exposing metal ion contaminants liberated in the course of the bulk etch and surface roughening to an acidic solution of a chelating agent 130 to inhibit reassociation of the liberated metal contaminants onto the process substrate. Optionally, native oxide removal is preceded by exposure to a solution of sulfuric acid and hydrogen peroxide, commonly referred to as piranha 102. Conventional piranha solution concentrations are operative herein with the understanding that reaction kinetics with organic materials found on the substrate surface have proportionality with solution active agent concentrations. Typically, mixtures of sulfuric acid, hydrogen peroxide and deionized water range from 1 to 10 percent sulfuric acid and 1 to 10 percent hydrogen peroxide. Preferably, a catalytic quantity of soluble metal sulfate is added to the aqueous sulfuric acid and hydrogen peroxide solution to catalyze removal of organic material. More preferably, aqueous soluble metal sulfate. Preferably, the metal ion of the sulfate does not contribute to photovoltaic efficiency degradation. A particularly preferred aqueous soluble metal sulfate is calcium sulfate. Without intending to be bound by a particular theory, it is believed that sulfate salt catalyzes organic material removal from a substrate surface. In the event the substrate is exposed to piranha solution at step 102, step 102 is followed by a rinse in deionized water 104. Preferably, the deionized water rinse 104 contains an ethylenediamine tetraacid having the formula

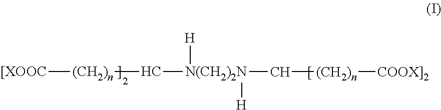

where n in each occurrence is independently an integer value between 0 and 6, and X is H, NR₄, Li, Na or K; where R in each occurrence is independently H or C₁-C₆ alkyl. Preferably, R in all occurrences is the same. Illustrative specific examples of NR₄ are ammonium cation, tetramethyl ammonium, and tetraethylammonium.

Representative ethylenediamine tetraacids of (I) include ethylenediamine disuccinic acid (EDDS), ethylenediamine dimalonic acid (EDDM), and ethylenediamine diglutaric acid (EDDG). It is appreciated that an inventive ethylenediamine tetraacid of Formula I has a similar K_{f} as ethylenediamine tetraacetic acid (EDTA) for copper and, more importantly, are biodegradable, in contrast to EDTA. It is also somewhat counterintuitive to choose a chelant with lower binding effectiveness than EDTA, but which has surprisingly shown excellent interfacial efficacy in this invention. Additionally, the combination of those chelants which also have high biocompatibility, that is, are readily decomposed via naturally occurring biological pathways is also not directly intuitive when evaluated against high chemical stability in the presence of oxidants like hydrogen peroxide, high pH like that found in caustic solutions, for example aqueous NH₄OH or KOH, or low pH such as that found in acidic solutions of, for example, HCl or HF.

The inventive ethylenediamine tetraacids of Formula I used herein are compatible with peroxide at both acidic and basic pHs and offer the further advantage of stabilizing peroxides against incidental degradation in solution thereby reducing peroxide usage rates. Optionally, the deionized water rinse 104 contains sodium (or ammonium) citrate operative at acidic pHs to bind metal ions and in particular calcium 2+ ions.

Ammonium salts, e.g., NR₄⁺, where R═H, CH₃, or longer chain alkyls, are preferred, whether as mono-, di-, tri-, or quaternary substituted salt of the free acid. More preferably, the ammonium diethylenediamine tetraacid is the tris- or tri-ammonium salt. The use of this salt is a further inventive step since active ammonium in solution is known to assist in formation of, in particular, Cu²⁺, Ni²⁺, and Ag⁺, water soluble complexes [Eduard Schweizer (1857). “Das Kupferoxyd-Ammoniak, ein Auflösungsmittel für die Pflanzenfaser”. J. Prakt. Chem. 72 (1): 109-1111. Although the actual dissolution mechanism found in this invention is not critical, we theorize that the combination of the ammonium cation and the diethylenediamine tetraacid anion lead to more effective binding of some metals through surface chemisorption of NH₄⁺ to the metal ion contaminant, building of a solvent sphere around that metal ion as an ammonia complex, and subsequent capture of this partially solvated metal/ammonium coordination complex by the chelant anion, ultimately forming a fully solvated metal-chelate which is carried away from the interface being cleaned.

It is appreciated that an ethylene diamine tetraacid (I) is readily added to other baths to which a substrate is exposed. While the composition of substrate processing baths changes with the specifics of the device being formed and the nature of the substrate, by way of example the ethylene diamine tetraacid (I) is readily added to HF oxide or phosphorosilicate glass (PSG) removal solutions. A deionized water (DIW) rinse, HCl solution, a peroxide solution (SC1, SC2), a KOH solution, NH₄OH solution, or a combination of peroxide with either HF or KOH active solutions. It is further appreciated that ethylene diamine tetraacid (I) is readily added to multiple baths used to process a substrate to further enhance chelation of polycationic metal contaminants. By way of example, HF etched solution, the immediately following DIW rinse, a PSG removal HF solution used post phosphorus implantation, each or all can contain ethylene diamine tetraacid (I). In the event that ethylene diamine tetraacid (I) residue is observed following a given step, it is appreciated that a conventional DIW rinse readily removes the same.

In this invention, a diethylenediamine tetraacid (I), if present in deionized water rinse 104, is present in concentrations ranging from 5 to 1000 parts per million. Preferably, diethylenediamine tetraacid (I), if present in deionized water rinse 104, is present in concentrations ranging from 10-500 parts per million. Most preferably, ethylenediamine tetraacid (I), if present in deionized water rinse 104, is present in concentrations ranging from 10 and 500 parts per million Like concentrations of diethylenediamine tetraacid (I) are operative in HF solutions. Optionally, the deionized water rinse 104 includes an ultrasonic energy input to facilitate substrate cleaning and removal of organic contaminants therefrom.

In processing silicon substrates, native oxide is removed from a silicon substrate through exposure to hydrofluoric (HF) solutions. Typical concentrations of hydrofluoric acid range from 0.5 to 50 mole percent, but a standard concentration is between 5-10% by weight, or roughly 2.5-5.0 molar. Optionally, the HF solution can also include and ethylenediamine acid of Formula I.

In the course of preparing photovoltaic silicon substrates, one side of the substrate is “textured”. This texturing helps capture sunlight (photons) and helps keep them trapped by internal reflection in the photovoltaic substrate until which time they create an electron/hole pair and can generate photocurrent. The photon enters the substrate, but absorption is not quantitative. Generally, there is a mirrored surface on the back side which reflects all unabsorbed photons back through the substrate. However, front side losses could be quite high if not re-reflected back into the substrate. A roughened surface effectively allows good internal reflection while maintaining transparency to incoming photons, usually with the addition of an anti-reflective thin film of silicon nitride, which further allows penetration of incoming photons and also helps provide for internal reflection of photons already in the bulk substrate. This surface texturing is generally thought to be required for any silicon based photovoltaic substrate, whether multi- or single-crystal. Preferably for a texturing step for multicrystalline silicon, an HF solution also includes a quantity of nitric acid to catalyze silicon dioxide etch (oxidation HF-etch). Nitric acid quantities present in the native oxide etch solution 110 range from 15 to 70 wt. percent. [ISES 2001 Solar World Congress, “Texturing Industrial Multicrystalline Silicon Solar Cells”, D. Macdonald et al., and U.S. Pat. No. 5,949,123—Solar cell including multi-crystalline silicon and a method of texturizing the surface of p-type multi-crystalline silicon]

Subsequent to removing a native oxide from a native photovoltaic substrate or from a surface texturing step with HF/HNO₃, the substrate is rinsed with deionized water 112. Optionally, the deionized water also includes ethylenediamine acids of Formula I. Optionally, the deionized water rinse 112 is expedited through simultaneous exposure to ultrasonic agitation.

Initial surface preparation, including removal of organic contaminants and particles is performed at step 120 with a basic peroxide aqueous solution. Preferably, the base is present as ammonium hydroxide. In the semiconductor industry, this is commonly referred to as “SC-1” or “standard-clean 1”. Sometimes in PV manufacturing, the “SC-1” sequence is not performed, but substituted for a bulk etch process which includes aqueous caustic solution and some isopropyl alcohol. The bulk etch and surface roughening removes particulate contaminants and can somewhat desorb trace metals such as gold, silver, copper, nickel, manganese and Fe, Cu, Cr or any other transition metal which might be entrained at the Si surface as an impurity during crystal growth while also removing large amounts of surface silicon. Preferably, the bulk etch and surface roughening 120 also includes an ethylenediamine tetraacid (I) alone or in combination with tetramethylammonium citrate. With the inclusion of chelating agents such as the diethylenediamine tetraacid (I), tetramethylammonium citrate (TMAC), other conventional chelating agent, or a combination thereof, desorbed trace metals are chelated and thereby precluded from chemisorption or physisorption back onto the etched and roughened surface of the substrate. This can be done in combination with the bulk cleaning step, or alone as simply a deionized water solution of the ethylenediamine tetraacid (I), at the convenience of the user, the point being, that the chemistry is not dependent upon the use of other etchants or chemical agents to show some efficacy. Hydrogen peroxide concentrations typically range from 5% to 30% and preferably are between 5% and 7%. Ethylenediamine tetraacid concentrations are typically between 5 and 1000 ppm and preferably between 10 and 500 ppm while TMAC is present in similar concentrations. Subsequent to exposure to the bulk etch and surface roughening solution 120, the substrate is rinsed with a deionized water rinse optionally containing an ethylenediamine tetraacid (I) 104′ which shares the attributes detailed above with respect to the deionized water rinse 104.

Bulk etching and surface roughening of single crystal silicon is more typically performed using an aqueous caustic base solution, often accompanied by a fixed amount of isopropanol, held at an elevated temperature of 80° C. to 100° C. This process has been shown to etch bulk material preferentially to a <100> crystal plane, resulting in a rough surface characterized by random small pyramidal structures of silicon. [Nishimoto, U.S. Pat. No. 6,197,611].

The now etched and surface roughened substrate, subsequent to rinse at step 104′, is then exposed to an acidic hydrogen peroxide aqueous solution in order to dissolve alkali ions and hydroxides of trivalent metal ions, as well as to desorb residual trace metals not liberated at step 120. Suitable acids illustratively include hydrochloric acid and sulfuric acid, but typically prefer hydrochloric acid. It is appreciated that other acids can be used upon assurance that unacceptable residual contaminants do not become associated with the substrate. The acidic peroxide dissolution of alkali ions and di and trivalent metal chlorides occurs at step 130. Preferably, the acidic peroxide solution includes an ethylenediamine tetraacid (I), citric acid, or a combination thereof in order to chelate liberated metal ions. The hydrogen peroxide concentration is typically between 3% and 30% and preferably between 1 and 5, while acid concentrations are generally less than 1 molar in concentration. The ethylenediamine tetraacid (I) is present in concentrations as detailed above with respect to step 120 while citric acid can be present in quantities similar to those detailed above with respect to step 120 for TMAC.

Subsequent to step 130, the now cleaned substrate is rinsed with deionized water optionally with simultaneous application of ultrasonics at step 132. It is appreciated that throughput of an inventive process 100 is promoted using, e.g., a Marangoni effect dryer with a volatile solvent such as isopropyl alcohol displacing water on the now cleaned photovoltaic substrate at step 134.

It is appreciated that the relative time associated with each of the aforementioned steps depends on factors including flow rates, concentration of active cleaning agents, temperature, and if ultrasonic energy is applied concurrently with exposure to the solutions. A preferred schematic flowchart for a silicon substrate photovoltaic is shown in FIG. 1B with dashed line boxes (steps that can be omitted) and bold line boxes (steps that can contain ethylene diamine tetracid (I)) relative to the conventional process.

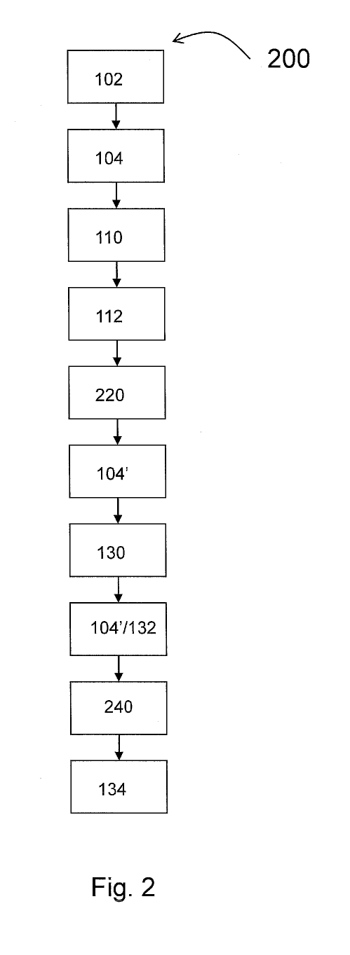

Referring now to FIG. 2, an alternate process for removing contaminants from a photovoltaic substrate is provided generally at 200, where like numerals used in common between FIGS. 1 and 2 have the meaning ascribed to the term above with respect to FIG. 1. The process 200 includes initial optional step 102 to remove organic material from the substrate surface. If optional step 102 is performed including exposing a substrate to a solution containing sulfuric acid, hydrogen peroxide and optionally small amounts of a sulfate metal salt, step 102 is followed by a deionized water rinse optionally with a concentration of an ethylenediamine tetraacid (I) 104. Native oxide removal represents the first essential step of the process 200 and occurs in HF solution at step 210 followed by deionized water rinse 112. Bulk etchant surface roughening is performed at step 102 by placing substrate now free of native oxide into a solution containing guanidine derivative that is both basic and water soluble. The solution used at step 102 is optionally augmented with ammonium hydroxide or other base to moderate pH to better control etch rate. Hydrogen peroxide is also optionally added with care taken to assure compatibility with the particular guanidine derivative. An ethylenediamine tetraacid (I) is optionally provided at levels as detailed with respect to step 120 of FIG. 1.

Subsequent to bulk etch and surface roughening 220 to yield an etched and surface roughened substrate, the substrate is rinsed with deionized water solution optionally containing ethylenediamine tetraacid (I) at step 104′. The substrate is thereafter exposed to an acidic peroxide solution containing an ethylenediamine tetraacid (I) at step 130 followed by repeated deionized water rinse 104′ or 132. Optionally, a final HF exposure is provided 240 to remove any oxide grown during the acidic peroxide step 103. As detailed with respect to FIG. 1, an optional Marangoni effect dryer step is provided to speed throughput 134. It is appreciated that other common methods of drying are also optionally used herein and include vacuum drying and an air knife.

It is appreciated that the claimed processes detailed above with respect to FIGS. 1 and 2 are amenable to manual batch process or automation. As is conventional to the art, process uniformity with high throughput is facilitated through the use of flowing tanks, scrubbers, ultrasonic agitation and computer controlled transfer mechanisms. Further, distinct substrates are preferably loaded into a cassette to facilitate handling during an inventive process 100 or 200.

In addition to a photovoltaic (solar) substrate other substrates amenable to an inventive cleaning process include a bare or pure silicon substrate, with or without doping, a substrate with epitaxial layers, a substrate incorporating one or more device layers at any stage of processing, other types of substrates incorporating one or more layers, or substrates for processing other apparatus and devices such as but not limited to light emitting diodes or laser diodes, flat panel displays, and multichip modules. However, to avoid obscuring the invention the following description will describe photovoltaic (solar) substrate cleaning in general and as an example of one embodiment will describe the use of the present invention in a scrubbing process.

The present invention is further detailed with respect to the following examples. These examples are not intended to limit the scope of the appended claims.

### Example 1

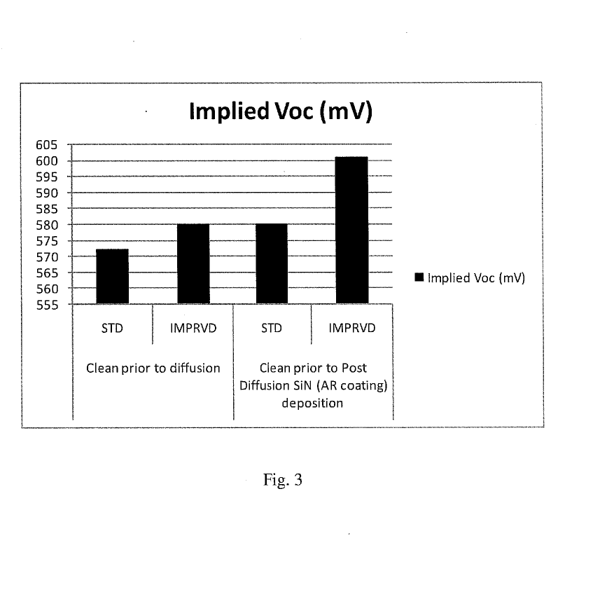

Crystalline silicon photovoltaic substrates are cleaned using a standard cleaning process and compared to identical substrates which are cleaned identically, except for adding a last, room temperature, 30 second dip in a 300 ppm tris-ammonium ethylenediamine disuccinnic acid (TA-EDDS) and deionized water solution, and final rinse with pure deionized water. Measurement of the effectiveness and impact of this seemingly subtle cleaning step is done indirectly by measuring the impact of the cleaning step on the photovoltaic electrical performance of the substrates after completing their processing. Electrical testing is done by measuring open circuit voltage (V_{OC}) of the silicon substrate as measured in millivolts (mV). In this example, the improvement is shown directly when the substrates are cleaned prior to dopant thermal activation; 1.4% absolute improvement, from 572 mV for the standard clean (control samples) to 580 mV for the clean with aqueous TA-EDDS after the standard clean. When identical wafers are cleaned prior to deposition of silicon nitride (applied as an encapsulant, front ohmic contact layer, and antireflective thin film), the improvement is even more dramatic; 3.6% improvement, from 580 mV for the standard (control samples) clean to 601 mV for the clean with aqueous TA-EDDS after the standard clean. Although the absolute improvement values shown can and would be a reflection of initial substrate quality, wetted cleaning time, and other factors, with improvement in performance being inversely proportional to the state of cleanliness of the original surface and bulk properties of the substrate, these results clearly show that use of this invention indeed improves final device electrical performance in a direct comparison where all other variables are kept identical. The results are shown in FIG. 3 as a bar graph plot test of Tris-ammonium EDDS in DI water (IMPRVD) versus conventional (STD); Concentration=300 ppm; 30 second quick dump rinse; T=ca. 22° C.; c-Si, implanted P.

### Example 2

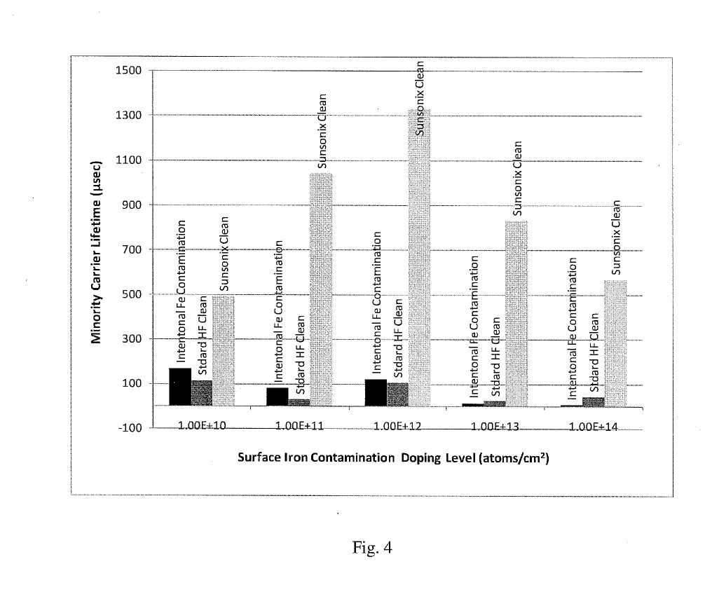

The efficacy of utilizing aqueous ethylenediamine tetraacids (I) for removing metal ions from a surface is demonstrated with a number of float-zone, single crystal silicon substrates that are prepared by standard semiconductor SC-1 and SC-2 cleans to provide uniform starting substrates which are then separated into three individual groups. In addition to control substrates amongst this grouping which remained uncontaminated and processed separately from the following to avoid cross-contamination, two groups are intentionally contaminated with various concentrations of Fe³⁺ (from aqueous Fe(NO₃)₃). These substrates are then cleaned. One of these two contaminated groups is cleaned using a standard HF-last type clean (10% HF in deionized water), and the other cleaned using this same solution formulation (but new solutions), but with the addition of 500 ppm of tris-ammonium ethylenediamine disuccinnic acid (TA-EDDS) to that HF solution. All groups are then thermally annealed at 750° C. for 30 minutes to “activate” any surface iron that might react with the silicon. This process models that which normal substrates might be subjected in a photovoltaics or semiconductor process during various high temperature steps seen in standard processing. Subsequent to this high temperature anneal, the substrates are evaluated for their minority carrier lifetime performance Like the previous example, this is an indirect indication of the level of iron contamination in the near surface region; iron in silicon is a mid-level band gap electrical trap—the more iron, the shorter the minority carrier lifetime. The results dramatically show an improvement in minority carrier lifetime, particularly at moderate surface contamination levels. This evidences dramatic improvement over both the control and standard industry clean by simply adding TA-EDDS to the standard HF clean, some samples by orders of magnitude over the corresponding standard clean. The results of these experiments are provided as bar graph plots in FIG. 4 for TA-EDDS (denoted as “SUNSONIX™ Clean”), as well for intentionally contaminated and HF clean only.

### Example 3

Multi-crystalline silicon substrates are first textured using the standard industry HF/HNO₃ process, rinsed with deionized water (DIW), treated with dilute KOH (to remove surface porosity from the bulk etch step), rinsed with DIW, treated with SC1 (to neutralize any KOH), rinsed with DIW, then treated with a dilute HF solution (to remove residual oxide grown during the KOH step), followed by a final DIW rinse and drying at 40° C. A group of control substrates then goes directly to a phosphorous doping step (forming the emitter), removal of the phosphorosilicate (PSG) glass formed during the annealing step using HF and DIW rinses, then continue to a silicon nitride deposition step. Other groups of these wafers are treated with a 15 second, 30 second, 45 second, and 60 second exposure to 10% HF/300 ppm TA-EDDS treatment, a 30 second DIW spray rinse, a 30 second DIW dip rinse, and dried. This second group then also has the same phosphorus doping steps and silicon nitride deposition performed as the control group. The control group showed an overall absolute photovoltaic efficiency of 15.28%. The substrates which underwent identical split-lot processing as the controls, except for the treatment with the HF/TA-EDDS step described showed an overall absolute photovoltaic efficiency of 15.44%, an increase of 0.16%. Although this seems a small absolute effect, the photovoltaics industry has an annual improvement goal of 0.05-0.1% in absolute photovoltaic response efficiency, so providing almost double that goal with the simple insertion of the TA-EDDS step is both dramatic and surprising in its magnitude. The results are provided in the following table.

TABLE
Performance of Photovoltaics for Timed Exposure to Inventive
Solution after Texturing Compared to
Conventional Running Production Line.

| Process | Voc (mV) | Isc | Eta |
|---|---|---|---|
| Inventive solution | 0.6062 ± 0.0022 | 7.999 ± 0.047 | 15.48 ± 0.19 |
| 15 sec. | | | |
| Inventive solution | 0.6065 ± 0.0021 | 7.997 ± 0.054 | 15.54 ± 0.20 |
| 30 sec. | | | |
| Inventive solution | 0.6049 ± 0.0029 | 7.987 ± 0.066 | 15.27 ± 0.25 |
| 45 sec. | | | |
| Inventive solution | 0.6057 ± 0.0023 | 8.011 ± 0.045 | 15.45 ± 0.19 |
| 60 sec. | | | |
| Running Line | 0.6049 ± 0.0029 | 7.996 ± 0.066 | 15.28 ± 0.23 |
| Comparative | | | |

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A process for removing contaminating metal from an insulator or semiconductor substrate to improve electrical performance comprising:
exposing the substrate to an aqueous solution of at least one compound of the formula: 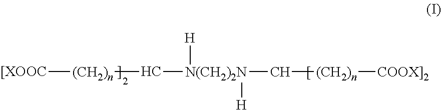
where n in each occurrence is independently an integer value between 0 and 6, and X is independently in each occurrence H, NR₄, Li, Na or K; where R in each occurrence is independently H or C₁-C₆ alkyl, to improve electrical performance of the substrate.

2. The process of claim 1 further comprising removing of a native oxide from the substrate prior to or concurrent with the exposing step.

3. The process of claim 1 wherein the compound of Formula I is present at between 5 and 1000 parts per million and at least one of X is NR₄.

4. The process of claim 3 wherein the compound of Formula I is ethylenediamine disuccinic and X in three occurrences is NR₄ and the compound is present at between 10 and 500 parts per million.

5. The process of claim 1 to wherein said aqueous solution contains at least one of peroxide or mineral acid.

6. The process of claim 5 wherein said aqueous solution is SC1 or SC2.

7. The process of claim 5 wherein said mineral acid is hydrochloric, nitric, or hydrofluoric.

8. The process of claim 5 wherein said aqueous solution is a base.

9. The process of claim 5 wherein said base is potassium hydroxide or ammonium hydroxide.

10. The process of claim 1 wherein the substrate is silicon and the contaminating metal is iron.

11. A process for removing contaminating metal from a silicon substrate comprising:
removing a native oxide from a native silicon substrate;
performing a bulk etch and surface roughening subsequent to the removing of the native oxide with an aqueous basic solution comprising at least one compound of the formula: 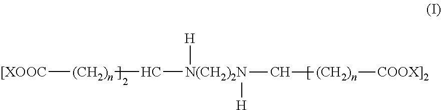
where n in each occurrence is independently an integer value between 0 and 6, and X is independently in each occurrence H, NR₄, Li, Na or K; where R in each occurrence is independently H or C₁-C₆ alkyl.

12. The process of claim 11 wherein the compound of Formula I is present at between 5 and 1000 parts per million.

13. The process of claim 11 wherein the compound of Formula I is ethylenediamine disuccinic and X in three occurrences is NR₄ and the compound is present at between 10 and 500 parts per million.

14. The process of claim 11 wherein said aqueous solution contains at least one of peroxide or mineral acid.

15. The process of claim 14 wherein said aqueous solution is SC1 or SC2.

16. The process of claim 14 wherein said mineral acid is hydrochloric, nitric, or hydrofluoric.

17. The process of claim 1 wherein said aqueous solution is a basic.

18. A kit for preparing a solution for removing contaminated metal from an insulator or semiconductor substrate to improve electrical performance comprising:
a 1 to 20 weight percent aqueous concentrate of at least one compound of the formula: 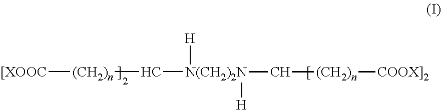
where n in each occurrence is independently an integer value between 0 and 6, and X is independently in each occurrence H, NR₄, Li or K, where R in each occurrence is independently H or C₁-C₆ alkyl;
together with instructions for the dilution of said concentrate to form the solution.

19. The kit of claim 18 wherein the compound of Formula I is present at between 5 and 1000 parts per million.
